(19) United States
(12) Patent Application Publication
(10) Pub. No.: US 2026/0313824 A1
(43) Pub. Date: Oct. 8, 2026

(54) IN-RACK ROUTED POWER CABLE WHIPS

(71) Applicant: DELL PRODUCTS L.P., Round Rock, TX (US)

(72) Inventors: Douglas Evan Messick, Austin, TX (US); Oscar Theodore Ligons, III, Georgetown, TX (US); Julian Yu-Hao Chen, Austin, TX (US)

(21) Appl. No.: 19/171,941

(22) Filed: Apr. 7, 2025

(51) Int. Cl. H05K 7/14

(52) U.S. Cl. CPC H05K 7/1492

(57) ABSTRACT

A power cable whip for a server rack includes first and second fixed elbows and an extension section. The first fixed elbow has a first orientation, and the second fixed elbow has a second orientation. The extension section extends between the first fixed elbow and the second fixed elbow. The extension section has a first length set to enable the power cable whip to fit within the server rack when the power cable is connected to a power shelf device.

### CROSS REFERENCE TO RELATED APPLICATION

Related subject matter is contained in co-pending U.S. Patent Application No. _____ (DC-143074) entitled “STRAIN RELIEF BAR IN A SERVER RACK,” filed of even date herewith, the disclosure of which is hereby incorporated by reference.

### FIELD OF THE DISCLOSURE

The present disclosure generally relates to information handling systems, and more particularly relates to routing power cable whips within a server rack.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A power cable whip for a server rack includes first and second fixed elbows and an extension section. The first fixed elbow may have a first orientation, and the second fixed elbow may have a second orientation. The extension section may extend between the first fixed elbow and the second fixed elbow. The extension section has a first length set to enable the power cable whip to fit within the server rack when the power cable is connected to a power shelf device.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIGS. 1 and 2 are block diagrams of a server rack including multiple information handling systems according to at least one embodiment of the present disclosure;

FIG. 3 is a diagram of a power cable whip according to at least one embodiment of the present disclosure;

FIG. 4 is a diagrams of multiple sets of power whips connected within a server rack according to at least one embodiment of the present disclosure;

FIG. 5 is a diagram of a strain relief bar according to at least one embodiment of the present disclosure;

FIG. 6 is a diagram of a top view of a portion of a server rack according to at least one embodiment of the present disclosure;

FIG. 7 is a diagram of a portion of a server rack according to at least one embodiment of the present disclosure; and

The use of the same reference symbols in different drawings indicates similar or identical items.

### DETAILED DESCRIPTION OF THE DRAWINGS

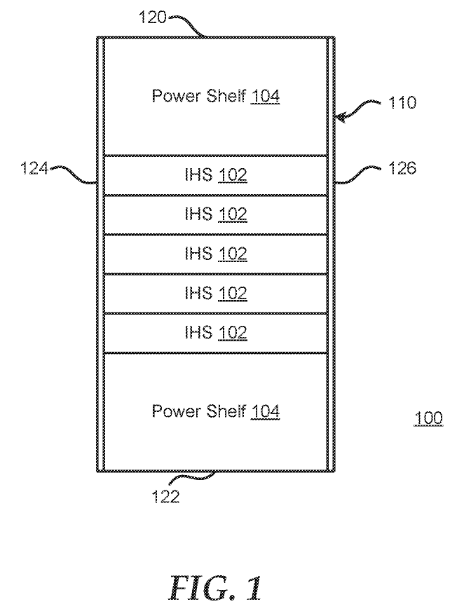

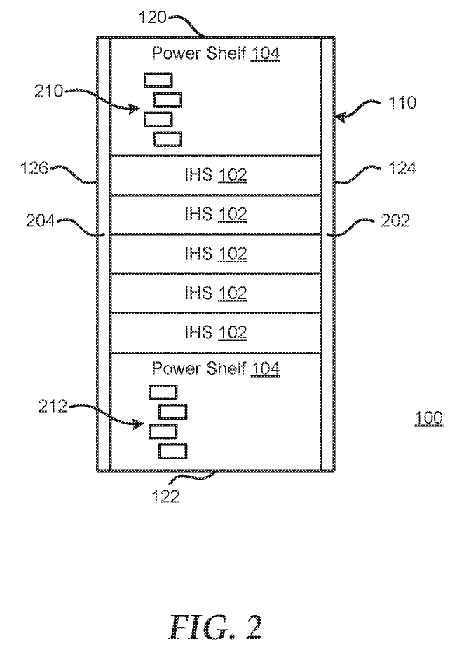

FIGS. 1 and 2 illustrate a server rack 100 housing multiple information handling systems 102 and power shelf devices 104 according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Server rack 100 further includes a housing 110, which in turn includes a top panel 120, a bottom panel 122, and side panels 124. In an example, one of power shelf devices 104 may be located near top panel 120 and the other power shelf device may be located near bottom panel 122. Server rack 100 may hold any suitable number of information handling systems 102 located between power shelf devices 104. As shown in FIG. 1, information handling systems 102 and power shelf devices 104 may substantially extend between side panels 124 and 126. In different examples, information handling systems 102 and power shelf devices 104 may be arranged in any suitable manner within server rack 100. Server rack 100 may house additional components without varying from the scope of this disclosure.

Referring to FIG. 2, a rear view of server rack 100 is illustrated. As shown in FIG. 2, server rack 100 further includes mounting rails 202 and 204, which may extend between top panel 120 and bottom panel 122. In an example, mounting rail 202 may extend substantially parallel to side panel 124 and mounting rail 204 may extend substantially parallel to side panel 126. Information handling systems 102 and power shelf devices 104 may connect to mounting rails 202 and 204, which in turn may secure the information handling systems and the power shelf devices within housing 110 of server rack 100.

In an example, power shelf devices 104 may receive alternating current (AC) power from a source outside of server rack 100. For example, one power shelf device 104 may receive the AC power through a set of plugs 210 and the other power shelf device 104 may receive the AC power through a set of plugs 212. Set of plugs 210 includes plugs 220, 222, 224, and 226. Set of plugs 212 includes plugs 230, 232, 234, and 236. Set of plugs 210 may be arranged in any suitable manner on the back panel of power shelf device 104 and set of plugs 212 may also be arranged in any suitable manner on the back panel of the other power shelf device 104.

As illustrated in FIG. 2, plugs 210 may be offset from one another, such that each plug is offset from the adjacent plug. For example, plugs 220 and 222 may be offset from each other, plugs 222 and 224 may be offset from each other, and plugs 224 and 226 may be offset from each other. In an example, plugs 220 and 224 may be substantially aligned and plugs 222 and 226 may be substantially aligned. In certain examples, plugs 212 may be offset from another, such that each plug is offset from the adjacent plug. For example, plugs 230 and 232 may be offset from each other, plugs 232 and 234 may be offset from each other, and plugs 234 and 236 may be offset from each other. In an example, plugs 230 and 234 may be substantially aligned and plugs 232 and 236 may be substantially aligned. During operation of power shelf devices 104, each of the power shelf devices may receive AC power from their corresponding plugs 210 and 212. Each power shelf device may convert the received AC power into a direct current (DC) power. Each power shelf device 104 may provide the converted DC power to one or more of information handling systems 102.

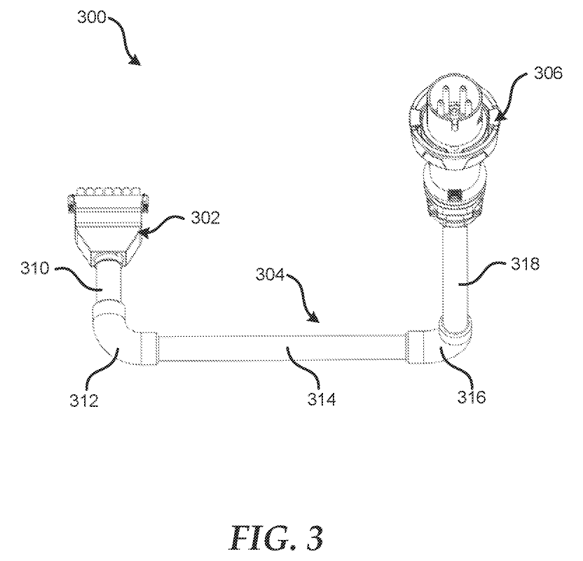

In certain examples, power shelf devices 104 may receive the AC power from AC power cable whips, such as power cable whip 300 of FIG. 3. In previous configurations of server racks and power cable whips, the whips were difficult to route within the server rack based on a power cable whip having a large bend radius. For example, a power cable whip capable of handling sixty Amperes of AC power may have an outer diameter of about thirty-one millimeters. This large power cable whip may have a bend radius of between one hundred and eighty millimeters to two hundred and forty-eight millimeters. In an example, server rack 100 may include rear door heat exchangers. However, if the power cable whips are not able to bend easily, the power cable whips may block access to the heat exchangers. Server rack 100 may be improved by AC power cable whips with pre-molded fixed elbows that reduce the bend radius of the power cables to enable greater access to the heat exchanges.

FIG. 3 illustrates a power cable whip 300 according to at least one embodiment of the present disclosure. Power cable whip 300 includes a connector 302, conduit sections 304, and an AC plug 306. Conduit sections 304 include an extension section 310, a fixed elbow 312, an extension section 314, a fixed elbow 316, and an extension section 318. Power cable whip 300 may include additional components without varying from the scope of this disclosure.

In an example, extension section 310 may extend between connector 302 and fixed elbow 312. Extension section 314 may extend between fixed elbow 312 and fixed elbow 316, and extension section 318 may extend between fixed elbow 316 and AC plug 306. In certain examples, connector 302 may plug into one of the plugs in set of plugs 210 or 212 of FIG. 2. AC plug 306 may connect with an AC power source through any suitable power cable located outside server rack 100 of FIGS. 1 and 2.

In certain examples, fixed elbows 312 and 316 may be permanently held in the respective orientations that are different than one another. For example, fixed elbow 312 may be permanently held in one plane of power cable whip 300. Similarly, fixed elbow 316 may be permanently held in another plane of power cable whip 300. In an example, the plane of fixed elbow 312 may be substantially perpendicular to the plane of fixed elbow 316 as illustrated in FIG. 3.

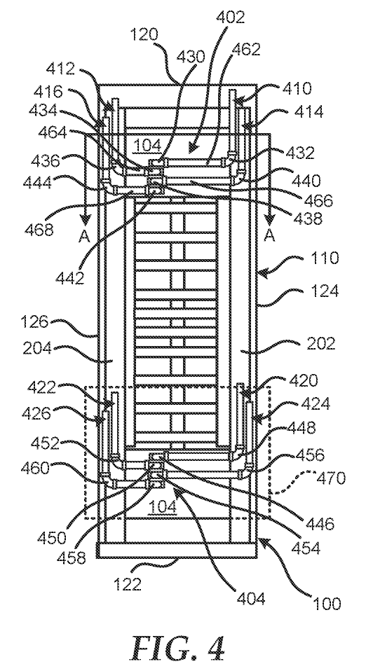

The combination of extension section 310 and fixed elbow 312 may provide distance between the back panel of a power shelf device, such as power shelf device 104 of FIG. 2. The length of extension section 310 and fixed elbow 312 may be any suitable length to enable extension section 314 to be located beyond components housed within server rack 100 of FIGS. 1 and 2. While this length may extend beyond the components, the length is short enough to enable extension section 314 to be located within server rack 100 of FIGS. 1 and 2. In an example, fixed elbow 316 may change the direction of conduit sections 304, such that extension portion 318 and AC plug may extend through top panel 120 of server rack 100 in FIGS. 1 and 2. While fixed elbow 312, as illustrated in FIG. 3, turns power cable whip 300 in a particular direction, a similarly located fixed elbow of a different power cable whip may turn that power cable whip in an opposite direction as will be described with respect to FIG. 4.

FIG. 4 illustrates sets of power cable whips 402 and 404 that are each connected to respective power shelf devices 104 within server rack 100 according to at least one embodiment of the present disclosure. Set of power cable whips 402 includes power cable whips 410, 412, 414, and 416. Set of power cable whips 404 includes power cable whips 420, 422, 424, and 426. Power cable whip 410 includes fixed elbows 430 and 432. Power cable whip 412 includes fixed elbows 434 and 436. Power cable whip 414 includes fixed elbows 438 and 440. Power cable whip 416 includes fixed elbows 442 and 444. Power cable whip 420 includes fixed elbows 446 and 448. Power cable whip 422 includes fixed elbows 450 and 452. Power cable whip 424 includes fixed elbows 454 and 456. Power cable whip 426 includes fixed elbows 458 and 460. Sets of power cable whips 402 and 404 may include additional components without varying from the scope of this disclosure.

In an example, each different power cable whip of set of power cable whips 402 may be connected to or plugged into a different plug of power shelf device 104, such as plugs 210 of FIG. 2. For example, power cable whip 410 may be connected to plug 220 of FIG. 2, power cable whip 412 may be connected to plug 222 of FIG. 2, power cable whip 414 may be connected to plug 224 of FIG. 2, and power cable whip 416 may be connected to plug 226 of FIG. 2. Each different power cable whip of set of power cable whips 404 may be connected to or plugged into a different plug of power shelf device 104, such as plugs 212 of FIG. 2. For example, power cable whip 420 may be connected to plug 230 of FIG. 2, power cable whip 422 may be connected to plug 232 of FIG. 2, power cable whip 424 may be connected to plug 234 of FIG. 2, and power cable whip 426 may be connected to plug 236 of FIG. 2.

As shown in FIG. 4, set of power cable whips 402 may exit power shelf device 104 in an alternating fashion and nest within side panels 124 and 126 of server rack 100. For example, fixed elbow 430 may be set in a direction to direct power cable whip 410 towards side panel 124 of housing 110, and fixed elbow 432 may be set in a direction to direct the power cable whip towards top panel 120. Alternatively, fixed elbow 434 may be set in an opposite direction to direct power cable whip 412 towards side panel 126, and fixed elbow 436 may be set in a direction to the direct power cable whip towards top panel 120. Fixed elbow 438 may be set in the direction to direct power cable whip 414 towards side panel 124, and fixed elbow 440 may be set in the direction to the direct power cable whip towards top panel 120. Fixed elbow 442 may be set in the direction to direct power cable whip 416 towards side panel 126, and fixed elbow 444 may be set in a direction to the direct power cable whip towards top panel 120. In an example, this arrangement of set of power cable whips 402 may enable greater access to the heat exchanger units in server rack 100.

In an example, each power cable whips 410, 412, 414, and 416 may have a corresponding extension section between the fixed elbows of the power cable. For example, power cable whip 410 includes an extension section 462 between fixed elbows 430 and 432. Similarly, power cable whip 412 includes an extension section 464 between fixed elbows 434 and 436. Power cable whip 414 includes an extension section 466 between fixed elbows 438 and 440. Power cable whip 416 includes an extension section 468 between fixed elbows 442 and 444. In certain examples, the lengths of extension sections 462, 464, 466, and 468 may differ from one extension section to the next. The different lengths of extension sections 462, 464, 466, and 468 may enable power cable whips 410, 412, 414, and 416 to be nested within side panels 124 and 126 of server rack 100. The lengths of extension sections 462, 464, 466, and 468 with respect to one another may fluctuate from the description herein without varying from the scope of this disclosure.

In certain examples, extension section 466 may be the longest section, such that fixed elbow 440 of power cable whip 414 is closest to side panel 124. In this situation, fixed elbow 440 may be adjacent to side panel 124 and mounting rail 202. Additionally, fixed elbow 440 may change the direction of power cable whip 414 from being perpendicular to side panel 124 and mounting rail 202 over the length of extension section 466 to cause the direction of power cable whip to be substantially parallel to the mounting rail and side panel. For example, an extension section connected to fixed elbow 440 may extend in a direction parallel to mounting rail 202 and side panel 124 as illustrated in FIG. 4.

In an example, extension section 462 may be the next longest section, such that fixed elbow 432 of power cable whip 410 is further from side panel 124 as compared to fixed elbow 440 of power cable whip 414. In this situation, fixed elbow 432 may be adjacent to side panel 124 and mounting rail 202. Additionally, fixed elbow 432 may change the direction of power cable whip 410 from perpendicular to side panel 124 and mounting rail 202 over the length of extension section 462 to cause the direction of power cable whip to be substantially parallel to the mounting rail and side panel. For example, an extension section connected to fixed elbow 432 may extend in a direction parallel to mounting rail 202 and side panel 126 as illustrated in FIG. 4.

In certain examples, extension section 468 may be the longest section in the direction of side panel 126, such that fixed elbow 444 of power cable whip 416 is closest to side panel 126. In this situation, fixed elbow 444 may be adjacent to side panel 126 and mounting rail 204. Additionally, fixed elbow 444 may change the direction of power cable whip 416 from being perpendicular to side panel 126 and mounting rail 202 over the length of extension section 468 to cause the direction of power cable whip to be substantially parallel to the mounting rail and side panel. For example, an extension section connected to fixed elbow 444 may extend in a direction parallel to mounting rail 202 and side panel 126 as illustrated in FIG. 4.

In an example, extension section 464 may be the next longest section in the direction of side panel 126. Based on the length of extension section 464, fixed elbow 436 of power cable whip 412 is further from side panel 126 as compared to fixed elbow 444 of power cable whip 416. In this situation, fixed elbow 436 may be adjacent to side panel 126 and mounting rail 202. Additionally, fixed elbow 436 may change the direction of power cable whip 412 from perpendicular to side panel 126 and mounting rail 202 over the length of extension section 464 to cause the direction of power cable whip to be substantially parallel to the mounting rail and side panel. For example, an extension section connected to fixed elbow 436 may extend in a direction parallel to mounting rail 202 and side panel 124 as illustrated in FIG. 4.

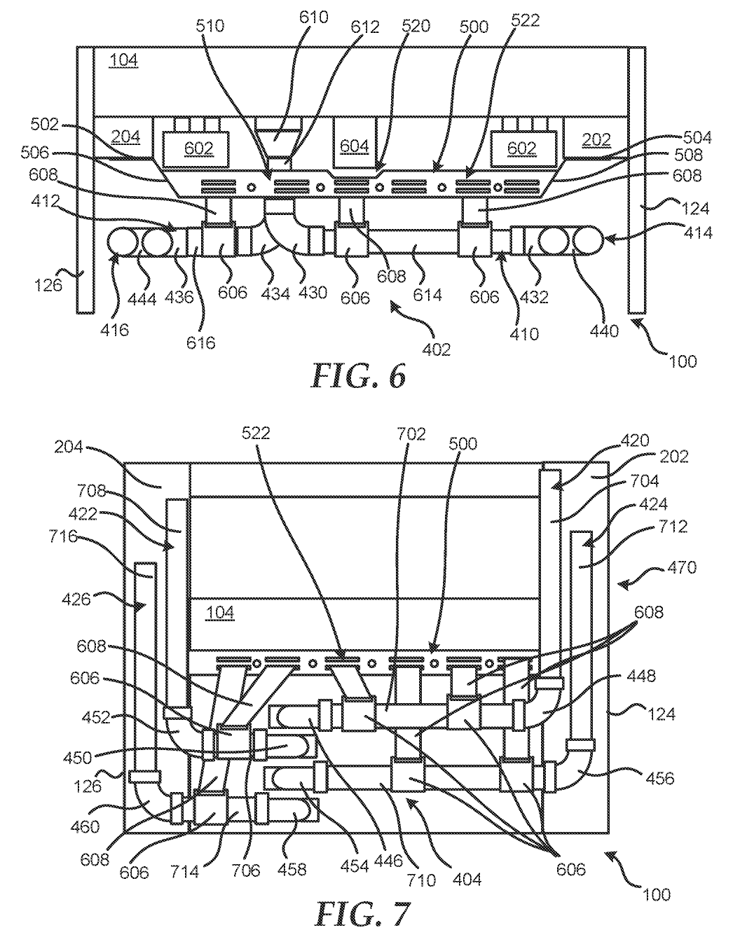

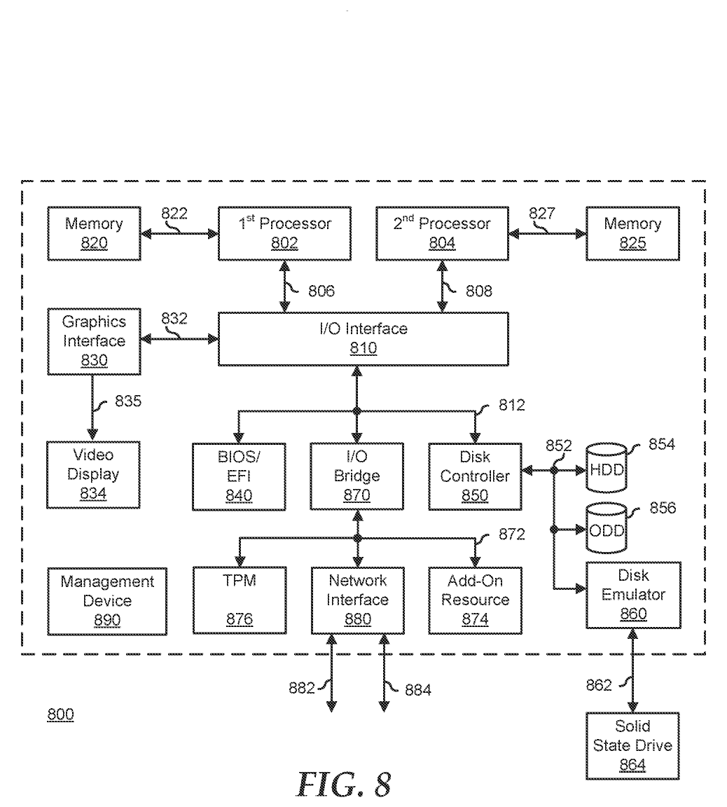

In certain examples, set of power cable whips 404 may exit power shelf device 104 in an alternating fashion and nest within side panels 124 and 126 of server rack 100. For example, fixed elbow 446 may be set in a direction to direct power cable whip 420 towards side panel 124 of housing 110, and fixed elbow 448 may be set in a direction to direct the power cable whip towards top panel 120. Alternatively, fixed elbow 450 may be set in an opposite direction to direct power cable whip 422 towards side panel 126, and fixed elbow 452 may be set in a direction to the direct power cable whip towards top panel 120. Fixed elbow 454 may be set in the direction to direct power cable whip 424 towards side panel 124, and fixed elbow 456 may be set in the direction to the direct power cable whip towards top panel 120. Fixed elbow 458 may be set in the direction to direct power cable whip 426 towards side panel 126, and fixed elbow 460 may be set in a direction to the direct power cable whip towards top panel 120. In an example, this arrangement of set of power cable whips 404 may enable greater access to the heat exchanger units in server rack 100. A portion of server rack 100 taken along A-A will be described with respect to FIG. 6 below. A portion 470 of server rack 100 will be described with respect to FIG. 7 below.

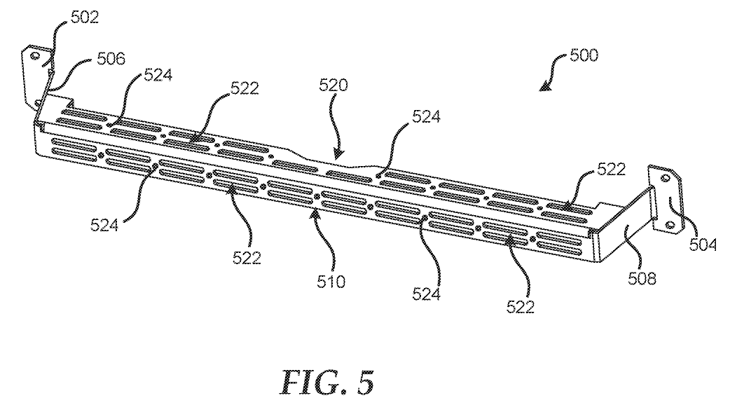

FIG. 5 illustrates a strain relief bar 500 according to at least one embodiment of the present disclosure. Strain relief bar 500 includes mounting brackets 502 and 504, extension portions 506 and 508, and main portion 510. Main portion 510 includes a recess portion 520 located substantially in the center of the main portion. Main portion 510 also includes multiple secure slots 522 and screw holes 524. Strain relief bar 500 may include additional components without varying from the scope of this disclosure.

In an example, mounting brackets 502 and 504 may be utilized to secure strain relief bar 500 to mounting rails 202 and 204 of FIGS. 2 and 6. Secure slots 522 may be utilized to attach support components and any other devices to strain relief bar 500. In certain examples, secure slots 522 may be grouped in pairs of secure slots and the pairs may be evenly distributed on main portion 510. Screw holes 524 may be utilized to attach additional components, such a leak detection components, to strain relief bar 500. In certain examples, one screw hole 524 may be located between two adjacent pairs of secure slots 522 as illustrated in FIG. 5. Strain relief bar 500 will be described in greater detail with respect to FIGS. 6 and 7 below.

FIG. 6 illustrates a top view of a portion of server rack 100 taken along line A-A in FIG. 4 according to at least one embodiment of the present disclosure. Server rack 100 includes liquid cooling manifolds 602, a bus bar 604, mounting components 606, and support components 608. In certain examples, mounting components 606 may be any suitable type of component that may hold an extension section of a power cable whip. In an example, support components 608 may be any suitable components that may hold the weight of a corresponding power cable whip. For example, support components 608 may be hook and loop straps, adjustable chains, or adjustable components. Power cable whip 410 includes a connector 610 and extension sections 612 and 614. Power cable whip 412 includes an extension section 616. Each power cable whip of set of power cable whips 402 may include similar components to power cable whip 300 of FIG. 3. Server rack 100 may include additional components without varying from the scope of this disclosure.

In an example, mounting bracket 502 is securely connected to mounting rail 202 and mounting bracket 504 is securely connected to mounting rail 204. Extension portions 506 and 508 may be substantially long so that main portion 510 is located beyond liquid cooling manifolds 602. In certain examples, extension portions 506 and 506 and main portion 510 may provide structural support to liquid cooling manifolds 602. For example, the amount of movement of liquid cooling manifolds 602 is limited by extension portion 506 and main portion 510 and the amount of movement of the other liquid cooling manifold 602 is limited by extension portion 508 and main portion 510. In an example, recess portion 520 may be substantially aligned with bus bar 604, such that the bus bar does not hit strain relief bar 500 when server rack 100 is moved.

In certain examples, extension section 612 may be any suitable length to enable fixed elbow 430 and extension section 614 to be located beyond main portion 510 of strain relief bar 500. Additionally, extension section 612 may be short enough to maintain power cable whip 410 within server rack 100. For example, the length of extension section 612 enables extension portion 614 and fixed elbow 432 of power cable whip 410 to be located at a length within server rack that is shorter than side panels 124 and 126.

In an example, power cable whip 412 may have a connector and an extension section extending from power shelf 104 that are substantially similar to connector 610 and extension section 612 of power cable whip 410. In certain examples, the extension section of power cable whip 412 may be any suitable length to enable fixed elbow 434 and extension section 616 to be located beyond main portion 510 of strain relief bar 500. Additionally, the extension section may be short enough to maintain power cable whip 412 within server rack 100. For example, the length of the extension section enables extension portion 616 and fixed elbow 436 of power cable whip 412 to be located at a length within server rack 100 that is shorter than side panels 124 and 126.

Power cable whip 414 may have a connector and an extension section extending from power shelf 104 that are substantially similar to connector 610 and extension section 612 of power cable whip 410. In certain examples, the extension section of power cable whip 414 may be any suitable length to enable fixed elbow 440 to be located beyond main portion 510 of strain relief bar 500. Additionally, the extension section may be short enough to maintain power cable whip 414 within server rack 100. For example, the length of the extension section enables fixed elbow 440 of power cable whip 414 to be located at a length within server rack 100 that is shorter than side panels 124 and 126.

Power cable whip 416 may have a connector and an extension section extending from power shelf 104 that are substantially similar to connector 610 and extension section 612 of power cable whip 410. In certain examples, the extension section of power cable whip 416 may be any suitable length to enable fixed elbow 444 to be located beyond main portion 510 of strain relief bar 500. Additionally, the extension section may be short enough to maintain power cable whip 416 within server rack 100. For example, the length of the extension section enables fixed elbow 444 of power cable whip 416 to be located at a length within server rack 100 that is shorter than side panels 124 and 126.

In certain examples, power cable whips 410, 412, 414, and 416 may be large and heavy, such that these power cable whips may need support to prevent strain from being exerted on the plugs of power shelf 104. In an example, one or more mounting components 606 may be connected to extension section 614 of power cable whip 410. Each of mounting components 606 may be attached to corresponding support components 608, which in turn may be secured on strain relief bar 500. In an example, the support components 608 may be secured to strain relief bar 500 via secure slots 522 on main portion 510 of the strain relief bar. In this example, the mounting components 606 and support components 608 may enable strain relief bar 500 to hold a substantial amount of the weight of power cable whip 410. Based on combination of mounting components 606, support components 608, and strain relief bar 500, the weight of power cable whip 410 may be removed from connector 610 and the corresponding plug of power shelf 104. The removal of power cable whip 410 weight removal may prevent damage or breakage of connector 610 and the plug of power shelf 104.

In an example, one or more mounting components 606 may be connected to extension section 616 of power cable whip 412. Each of mounting components 606 may be attached to corresponding support components 608, which in turn may be secured on strain relief bar 500. As described above with respect to power cable whip 410, mounting components 606 and support components 608 may enable strain relief bar 500 to hold a substantial amount of the weight of power cable whip 412. Based on combination of mounting components 606, support components 608, and strain relief bar 500, the weight of power cable whip 412 may be removed from the connector of the power cable whip and the corresponding plug of power shelf 104. The removal of power cable whip 412 weight removal may prevent damage or breakage of the connector and the plug of power shelf 104.

As described above with respect to power cable whips 410 and 412, mounting components 606 and support components 608 may enable strain relief bar 500 to hold a substantial amount of the weight of power cable whips 414 and 416. Based on combination of mounting components 606, support components 608, and strain relief bar 500, the weight of power cable whips 414 and 416 may be removed from the corresponding connector of the power cable whips and the corresponding plugs of power shelf 104. The removal of power cable whip 414 and 416 weight removal may prevent damage or breakage of the connectors and the plugs of power shelf 104.

FIG. 7 illustrates portion 470 of server rack 100 according to at least one embodiment of the present disclosure. Power cable whip 420 includes extension sections 702 and 704. Power cable whip 422 includes extension sections 706 and 708. Power cable whip 424 includes extension sections 710 and 712. Power cable whip 426 includes extension sections 714 and 716. Server rack 100 and power cable whips 420, 422, 424, and 426 may include additional components without varying from the scope of this disclosure.

In an example, each power cable whips 420, 422, 424, and 426 may have a corresponding extension section between the fixed elbows of the power cable whip. For example, extension section 702 of power cable whip 420 is located between fixed elbows 446 and 448. Similarly, extension section 706 of power cable whip 422 is located between fixed elbows 450 and 452. Extension section 710 of power cable whip 424 is located between fixed elbows 454 and 456. Extension section 714 of power cable whip 426 is located between fixed elbows 458 and 460. In certain examples, the lengths of extension sections 462, 464, 466, and 468 may differ from one extension section to the next. The different lengths of extension sections 702, 706, 710, and 714 may enable power cable whips 420, 422, 424, and 426 to be nested within side panels 124 and 126 of server rack 100. The lengths of extension sections 702, 706, 710, and 714 with respect to one another may fluctuate from the description herein without varying from the scope of this disclosure.

In certain examples, extension section 710 may be the longest section, such that fixed elbow 456 of power cable whip 424 is closest to side panel 124. In this situation, fixed elbow 456 may be adjacent to side panel 124 and mounting rail 202. Additionally, fixed elbow 456 may change the direction of power cable whip 424 from being perpendicular to side panel 124 and mounting rail 202 over the length of extension section 710 to cause the direction of the power cable whip to be substantially parallel to the mounting rail and side panel. For example, extension section 712 connected to fixed elbow 456 may extend in a direction parallel to mounting rail 202 and side panel 124 as illustrated in FIG. 7.

In an example, extension section 702 may be the next longest section, such that fixed elbow 448 of power cable whip 420 is further from side panel 124 as compared to fixed elbow 456 of power cable whip 424. In this situation, fixed elbow 448 may be adjacent to side panel 124 and mounting rail 202. Additionally, fixed elbow 448 may change the direction of power cable whip 420 from perpendicular to side panel 124 and mounting rail 202 over the length of extension section 702 to cause the direction of the power cable whip to be substantially parallel to the mounting rail and side panel. For example, extension section 704 connected to fixed elbow 448 may extend in a direction parallel to mounting rail 202 and side panel 124 as illustrated in FIG. 4.

In certain examples, extension section 714 may be the longest section in the direction of side panel 126, such that fixed elbow 460 of power cable whip 426 is closest to side panel 126. In this situation, fixed elbow 460 may be adjacent to side panel 126 and mounting rail 204. Additionally, fixed elbow 460 may change the direction of power cable whip 426 from being perpendicular to side panel 126 and mounting rail 202 over the length of extension section 714 to cause the direction of the power cable whip to be substantially parallel to the mounting rail and side panel. For example, extension section 716 connected to fixed elbow 460 may extend in a direction parallel to mounting rail 202 and side panel 126 as illustrated in FIG. 7.

In an example, extension section 706 may be the next longest section in the direction of side panel 126. Based on the length of extension section 706, fixed elbow 452 of power cable whip 422 is further from side panel 126 as compared to fixed elbow 460 of power cable whip 426. In this situation, fixed elbow 452 may be adjacent to side panel 126 and mounting rail 202. Additionally, fixed elbow 452 may change the direction of power cable whip 422 from perpendicular to side panel 126 and mounting rail 202 over the length of extension section 706 to cause the direction of the power cable whip to be substantially parallel to the mounting rail and side panel. For example, extension section 708 connected to fixed elbow 452 may extend in a direction parallel to mounting rail 202 and side panel 126 as illustrated in FIG. 4.

In certain examples, power cable whips 420, 422, 424, and 426 may be large and heavy, such that these power cable whips may need support to prevent strain from being exerted on the plugs of power shelf 104. In an example, one or more mounting components 606 may be connected to extension section 702 of power cable whip 420. Each of mounting components 606 may be attached to corresponding support components 608, which in turn may be secured on strain relief bar 500. In an example, the support components 608 may be secured to strain relief bar 500 via secure slots 522 on main portion 510 of the strain relief bar. In this example, the mounting components 606 and support components 608 may enable strain relief bar 500 to hold a substantial amount of the weight of power cable whip 420. Based on combination of mounting components 606, support components 608, and strain relief bar 500, the weight of power cable whip 420 may be removed from the connector of the power cable whip and the corresponding plug of power shelf 104. The removal of power cable whip 420 weight removal may prevent damage or breakage of its connector and the plug of power shelf 104.

In an example, one or more mounting components 606 may be connected to extension section 706 of power cable whip 422. Each of mounting components 606 may be attached to corresponding support components 608, which in turn may be secured on strain relief bar 500. As described above with respect to power cable whip 420, mounting components 606 and support components 608 may enable strain relief bar 500 to hold a substantial amount of the weight of power cable whip 422. Based on combination of mounting components 606, support components 608, and strain relief bar 500, the weight of power cable whip 422 may be removed from the connector of the power cable whip and the corresponding plug of power shelf 104. The removal of power cable whip 422 weight removal may prevent damage or breakage of the connector and the plug of power shelf 104.

As described above with respect to power cable whips 420 and 422, mounting components 606 and support components 608 may enable strain relief bar 500 to hold a substantial amount of the weight of power cable whips 424 and 426. For example, one or more mounting components 606 may be connected to extension section 710 of power cable whip 424 and one or more mounting components 606 may be connected to extension section 714 of power cable whip 426. Support components 608 may be connected between these mounting components 606 and corresponding secure slots 522 of strain relief bar 500. Based on combination of mounting components 606, support components 608, and strain relief bar 500, the weight of power cable whips 424 and 426 may be removed from the corresponding connectors of the power cable whips and the corresponding plugs of power shelf 104. The removal of power cable whip 424 and 426 weight removal may prevent damage or breakage of the connectors and the plugs of power shelf 104.

FIG. 8 shows a generalized embodiment of an information handling system 800 according to an embodiment of the present disclosure. Information handling system 800 may be substantially similar to information handling systems 102 of FIG. 1. Further, information handling system 800 can include processing resources for executing machine-executable code, such as a central processing unit (CPU), a programmable logic array (PLA), an embedded device such as a System-on-a-Chip (SoC), or other control logic hardware. Information handling system 800 can also include one or more computer-readable medium for storing machine-executable code, such as software or data. Additional components of information handling system 800 can include one or more storage devices that can store machine-executable code, one or more communications ports for communicating with external devices, and various input and output (I/O) devices, such as a keyboard, a mouse, and a video display. Information handling system 800 can also include one or more buses operable to transmit information between the various hardware components.

Information handling system 800 can include devices or modules that embody one or more of the devices or modules described below and operates to perform one or more of the methods described below. Information handling system 800 includes a processors 802 and 804, an input/output (I/O) interface 810, memories 820 and 825, a graphics interface 830, a basic input and output system/universal extensible firmware interface (BIOS/UEFI) module 840, a disk controller 850, a hard disk drive (HDD) 854, an optical disk drive (ODD) 856 , a disk emulator 860 connected to an external solid state drive (SSD) 864, an I/O bridge 870, one or more add-on resources 874, a trusted platform module (TPM) 876, a network interface 880, a management device 890, and a power supply 895. Processors 802 and 804, I/O interface 810, memory 820, graphics interface 830, BIOS/UEFI module 840, disk controller 850, HDD 854, ODD 856, disk emulator 860, SSD 864, I/O bridge 870, add-on resources 874, TPM 876, and network interface 880 operate together to provide a host environment of information handling system 800 that operates to provide the data processing functionality of the information handling system. The host environment operates to execute machine-executable code, including platform BIOS/UEFI code, device firmware, operating system code, applications, programs, and the like, to perform the data processing tasks associated with information handling system 800.

In the host environment, processor 802 is connected to I/O interface 810 via processor interface 806, and processor 804 is connected to the I/O interface via processor interface 808. Memory 820 is connected to processor 802 via a memory interface 822. Memory 825 is connected to processor 804 via a memory interface 827. Graphics interface 830 is connected to I/O interface 810 via a graphics interface 832 and provides a video display output 836 to a video display 834. In a particular embodiment, information handling system 800 includes separate memories that are dedicated to each of processors 802 and 804 via separate memory interfaces. An example of memories 820 and 830 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 840, disk controller 850, and I/O bridge 870 are connected to I/O interface 810 via an I/O channel 812. An example of I/O channel 812 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 810 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 840 includes BIOS/UEFI code operable to detect resources within information handling system 800, to provide drivers for the resources, initialize the resources, and access the resources. BIOS/UEFI module 840 includes code that operates to detect resources within information handling system 800, to provide drivers for the resources, to initialize the resources, and to access the resources.

Disk controller 850 includes a disk interface 852 that connects the disk controller to HDD 854, to ODD 856, and to disk emulator 860. An example of disk interface 852 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 860 permits SSD 864 to be connected to information handling system 800 via an external interface 862. An example of external interface 862 includes a USB interface, an IEEE 4394 (Firewire) interface, a proprietary interface, or a combination thereof. Alternatively, solid-state drive 864 can be disposed within information handling system 800.

I/O bridge 870 includes a peripheral interface 872 that connects the I/O bridge to add-on resource 874, to TPM 876, and to network interface 880. Peripheral interface 872 can be the same type of interface as I/O channel 812 or can be a different type of interface. As such, I/O bridge 870 extends the capacity of I/O channel 812 when peripheral interface 872 and the I/O channel are of the same type, and the I/O bridge translates information from a format suitable to the I/O channel to a format suitable to the peripheral channel 872 when they are of a different type. Add-on resource 874 can include a data storage system, an additional graphics interface, a network interface card (NIC), a sound/video processing card, another add-on resource, or a combination thereof. Add-on resource 874 can be on a main circuit board, on separate circuit board or add-in card disposed within information handling system 800, a device that is external to the information handling system, or a combination thereof.

Network interface 880 represents a NIC disposed within information handling system 800, on a main circuit board of the information handling system, integrated onto another component such as I/O interface 810, in another suitable location, or a combination thereof. Network interface device 880 includes network channels 882 and 884 that provide interfaces to devices that are external to information handling system 800. In a particular embodiment, network channels 882 and 884 are of a different type than peripheral channel 872 and network interface 880 translates information from a format suitable to the peripheral channel to a format suitable to external devices. An example of network channels 882 and 884 includes InfiniBand channels, Fibre Channel channels, Gigabit Ethernet channels, proprietary channel architectures, or a combination thereof. Network channels 882 and 884 can be connected to external network resources (not illustrated). The network resource can include another information handling system, a data storage system, another network, a grid management system, another suitable resource, or a combination thereof.

Management device 890 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 800. In particular, management device 890 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 800, such as system cooling fans and power supplies. Management device 890 can include a network connection to an external management system, and the management device can communicate with the management system to report status information for information handling system 800, to receive BIOS/UEFI or system firmware updates, or to perform other task for managing and controlling the operation of information handling system 800.

Management device 890 can operate off of a separate power plane from the components of the host environment so that the management device receives power to manage information handling system 800 when the information handling system is otherwise shut down. An example of management device 890 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 890 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A power cable whip for a server rack, the power cable whip comprising:
a first fixed elbow having a first orientation;
a second fixed elbow having a second orientation; and
a first extension section extending between the first fixed elbow and the second fixed elbow, wherein the first extension section has a first length set to enable the power cable whip to fit within the server rack when the power cable whip is connected to a power shelf device.

2. The power cable whip of claim 1, further comprising:
a connector; and
a second extension section extending between the connector and the fixed first elbow, wherein the second extension section is permanently positioned perpendicular to the first extension section.

3. The power cable whip of claim 1, wherein the first length is based on a set distance between a plug on the power shelf device and a side panel of the server rack.

4. The power cable whip of claim 1, wherein the first orientation is in a first plane and the second orientation is in a second plane.

5. The power cable whip of claim 4, wherein the first plane is perpendicular to the second plane.

6. The power cable whip of claim 1, wherein the first extension section extends in a direction perpendicular to a side panel of the server rack when the power cable whip is connected to the power shelf device.

7. A set of power cable whips comprising:
a first power cable whip including:
a first fixed elbow having a first orientation;
a second fixed elbow having a second orientation; and
a first extension section extending between the first fixed elbow and the second fixed elbow, wherein the first extension section has a first length set to enable the first power cable whip to fit within a server rack when the first power cable whip is connected to a power shelf device; and
a second power cable whip including:
a third fixed elbow having a third orientation, wherein the third orientation is opposite of the first orientation;
a fourth fixed elbow having the second orientation; and
a second extension section extending between the third fixed elbow and the fourth fixed elbow, wherein the second extension section has a second length set to enable the second power cable whip to fit within the server rack when the second power cable whip is connected to the power shelf device.

8. The set of power cable whips of claim 7, wherein the first power cable whip further comprises:
a first connector; and
a third extension section extending between the first connector and the first fixed elbow, wherein the third extension section is permanently positioned perpendicular to the first extension section.

9. The set of power cable whips of claim 8, wherein the second power cable whip further comprises:
a second connector; and
a fourth extension section extending between the second connector and the third fixed elbow, wherein the fourth extension section is permanently positioned perpendicular to the second extension section.

10. The set of power cable whips of claim 7, wherein the first length is based on a first set distance between a first plug on the power shelf device and a first side panel of the server rack.

11. The set of power cable whips of claim 10, wherein the second length is based on a second set distance between a second plug on the power shelf device and a second side panel of the server rack.

12. The set of power cable whips of claim 7, wherein the first orientation is in a first plane and the second orientation is in a second plane.

13. The set of power cable whips of claim 12, wherein the first plane is perpendicular to the second plane.

14. The set of power cable whips of claim 7, wherein the first extension section and the second extension section both extend in a direction perpendicular to side panels of the server rack when the first power cable whip and the second power cable whip are connected to the power shelf device.

15. A system comprising:
an information handling system;
a power shelf device to provide power to the information handling system;
a server rack to house the information handling system and the power shelf device, the server rack including:
a top panel, a bottom panel, and first and second side panels; and
a set of power cable whips located within the server rack, the set of power cable whips includes:
a first power cable whip including:
a first fixed elbow having a first orientation;
a second fixed elbow having a second orientation; and
a first extension section extending between the first fixed elbow and the second fixed elbow, wherein the first extension section has a first length set to enable the first power cable whip to fit within the server rack when the first power cable whip is connected to the power shelf device; and
a second power cable whip including:
a third fixed elbow having a third orientation, wherein the third orientation is opposite of the first orientation;
a fourth fixed elbow having the second orientation; and
a second extension section extending between the third fixed elbow and the fourth fixed elbow, wherein the second extension section has a second length set to enable the second power cable whip to fit within the server rack when the second power cable whip is connected to the power shelf device.

16. The system of claim 15, wherein the first length is based on a first set distance between a first plug on the power shelf device and the first side panel of the server rack, and wherein the second length is based on a second set distance between a second plug on the power shelf device and the second side panel of the server rack.

17. The system of claim 15, wherein the first orientation is in a first plane and the second orientation is in a second plane.

18. The system of claim 17, wherein the first plane is perpendicular to the second plane.

19. The system of claim 15, wherein the first extension section and the second extension section both extend in a direction perpendicular to the first and second side panels of the server rack when the first power cable whip and the second power cable whip are connected to the power shelf device.

20. The system of claim 15, wherein the first power cable whip further includes:
a third extension section extending from the second fixed elbow parallel to the first side panel and perpendicular to the top panel and the bottom panel.
